(19) United States
(12) Patent Application Publication
(10) Pub. No.: US 2025/0244676 A1
(43) Pub. Date: Jul. 31, 2025

(54) PHOTORESIST NOZZLE ULTRASONIC MONITORING SYSTEM AND METHOD OF OPERATING THE SAME

(71) Applicant: SANDISK TECHNOLOGIES LLC, ADDISON, TX (US)

(72) Inventors: Yutaka ISHIGURO, Yokkaichi (JP); Tomohiro NISHIWAKI, Yokkaichi (JP); Shoichi TANIGUCHI, Yokkaichi (JP)

(21) Appl. No.: 18/425,948

(22) Filed: Jan. 29, 2024

(51) Int. Cl. G03F 7/30; G03F 7/00; H01L 21/67

(52) U.S. Cl. CPC G03F 7/3014; G03F 7/70808; H01L 21/6708; H01L 21/67225

(57) ABSTRACT

A method includes providing a photoresist material into a dispenser nozzle having an orifice, emitting transmitted ultrasound waves through the photoresist material in the dispenser nozzle toward the orifice, detecting reflected ultrasound waves, and determining a property of the photoresist material or the nozzle by analyzing a waveform of the detected reflected ultrasound waves.

### FIELD

The present disclosure relates generally to the field of semiconductor device manufacturing method and apparatus, and specifically to a photoresist nozzle ultrasonic monitoring system and methods for operating the same.

### BACKGROUND

A photoresist layer is deposited over a semiconductor device substrate and is then photolithographically patterned to function as a mask during subsequent etching of the semiconductor device. However, presence of bubbles, dust, voids and/or protrusions in the photoresist layer may cause defects to the formed in the semiconductor device.

### SUMMARY

According to an aspect of the present disclosure, a method includes providing a photoresist material into a dispenser nozzle having an orifice, emitting transmitted ultrasound waves through the photoresist material in the dispenser nozzle toward the orifice, detecting reflected ultrasound waves, and determining a property of the photoresist material or the nozzle by analyzing a waveform of the detected reflected ultrasound waves.

According to another aspect of the present disclosure, a photoresist dispenser comprises a dispenser head; a dispenser nozzle having an orifice configured to dispense a photoresist material, wherein the dispenser nozzle is connected to the dispenser head; and an ultrasonic unit mounted on or adjacent to the dispenser head and comprising: an ultrasonic wave generator configured to emit a transmitted ultrasound waves through the nozzle toward the orifice; and an ultrasonic wave detector configured to detect reflected ultrasound waves.

### BRIEF DESCRIPTION OF THE DRAWINGS

FIG. 1 schematically illustrates a dispenser nozzle and a photoresist layer dispensed from the dispenser nozzle onto a semiconductor device substrate during different photoresist material dispensation steps.

FIG. 2 is a schematic representation of a photoresist dispensation system of an embodiment of the present disclosure.

FIGS. 3A, 3B, and 3C are various views of a single-head photoresist dispenser according to an embodiment of the present disclosure. FIG. 3B is a top-down view. FIG. 3A is a front view. FIG. 3C is a side view.

FIGS. 4A, 4B, and 4C are various views of a multi-head photoresist dispenser according to an embodiment of the present disclosure. FIG. 4B is a top-down view. FIG. 4A is a front view. FIG. 4C is a side view.

FIG. 5 shows various types of defects that may be present within, or around, a dispenser nozzle and ultrasound waveforms generated by such defects.

FIG. 6 illustrates a method of measuring a material property of a photoresist material employing a photoresist dispensation system according to an embodiment of the present disclosure.

FIG. 7 is a graph illustrating the dependence of the speed of the ultrasound within a photoresist material as a function of temperature and as a function of a concentration of photoactive components according to an embodiment of the present disclosure.

### DETAILED DESCRIPTION

The photoresist material is dispensed over a semiconductor device substrate from a photoresist dispenser having a photoresist dispenser nozzle. The present inventors realized that photoresist material within a photoresist dispenser may have various problems, such as protrusion and overhang of the photoresist material outside an orifice of a photoresist dispenser nozzle, excessive suck-back of the photoresist material into the dispenser nozzle, foreign materials (e.g. dust) or bubbles within the photoresist material, foreign materials at or around the orifice of the dispenser nozzle, or deterioration of the photoresist material composition inside the photoresist nozzle. Such problems may cause corresponding defects in the photoresist layer located over the semiconductor device substrate, which may lead to defects in the semiconductor device. The embodiments of the present disclosure are directed to an ultrasonic photoresist monitoring system and methods for operating the same, the various aspects of which are described below. The system and method detect defects the photoresist material located in the photoresist dispenser nozzle and/or at detect foreign materials (e.g., dust) in and/or around the photoresist dispenser nozzle.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

According to an aspect of the present disclosure, a photoresist dispenser including an ultrasonic detector unit for a photoresist dispenser head is provided. The ultrasonic unit includes an ultrasonic wave generator and an ultrasonic wave detector. A dispenser nozzle, a temperature sensor, and conduit interconnections are also provided. An ultrasonic waves can be emitted from the ultrasonic wave generator along an axial direction of the dispenser nozzle, and travels downward toward the orifice of the dispenser nozzle, and is reflected at various locations including a physically exposed surface of the photoresist material, any foreign material within the photoresist material or at, or around, the orifice. The reflected ultrasonic waves are detected by the ultrasonic wave detector, and are analyzed to determine various geometrical features of, or around, the photoresist material or the material property of the photoresist material. The photoresist dispenser may have a single dispenser head and a single dispenser nozzle, or may have multiple dispenser heads and multiple dispenser nozzles. The photoresist dispenser may be inspected prior to operation for dispensing a photoresist material on a product wafer to check the level of photoresist suck-back after dispensation, to check for presence of any foreign material within the photoresist material or around the orifice, and to check for the concentration of photoactive components in the photoresist material. The various aspects of the present disclosure are described with reference to accompanying drawings below.

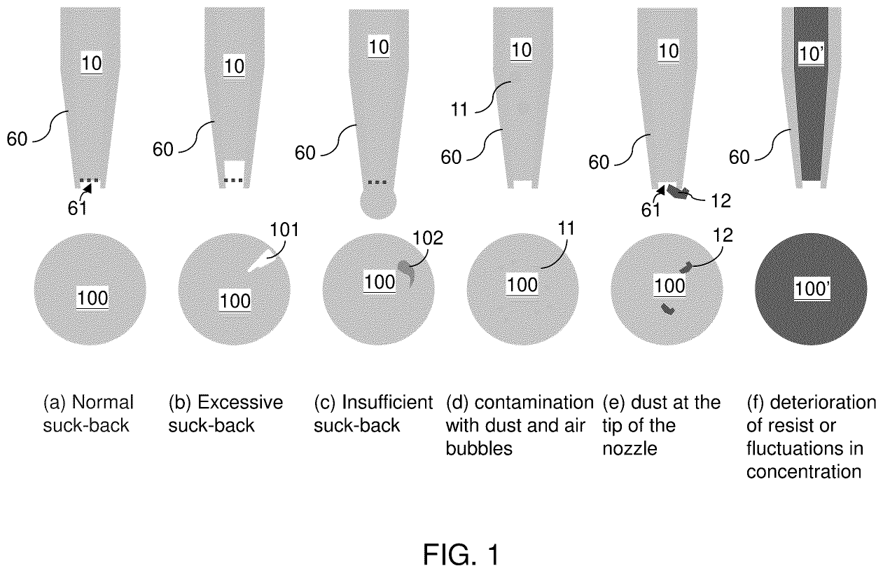

FIG. 1 illustrates an ideal configuration and various types of geometrical defects and a defective photoresist material composition that can occur within or around a photoresist dispenser nozzle 60 containing a photoresist material (10, 10′). Various vertical cross-sectional views a dispenser nozzle 60 are shown in an upper region of FIG. 1, and top-down views of the photoresist material (10, 10′) layer dispensed from the dispenser nozzle 60 onto a semiconductor device substrate are shown in a lower region of FIG. 1.

Referring to configuration (a) of FIG. 1, a dispenser nozzle 60 with a photoresist material 10 is illustrated, which has a physically exposed surface at a normal suck-back position after dispensation of the photoresist material 10. Configuration (a) is the ideal configuration at which a fully functional dispenser nozzle 60 should be after each dispensation cycle that dispenses a portion of the photoresist material 10. The degree of suck-back of the photoresist material 10 after dispensation is optimal in configuration (a). Generally, the degree of suck-back of the photoresist material 10 is controlled by an internal suck-back control mechanism. For example, a solenoid valve may close rapidly after dispensing a portion of a photoresist material 10 to create a sudden negative pressure within the dispenser nozzle 60. Alternatively, a controlled burst of compressed air may be employed to generate a negative pressure within the dispenser nozzle 60, thereby retracting the photoresist material 10 into the dispenser nozzle 60. Alternative mechanisms for retracting the photoresist material 10 after dispensation may be employed.

The photoresist material 10 within the dispenser nozzle 60 in configuration (a) does not include any foreign material therein. Also, there is no foreign material at or near the orifice 61 of the dispenser nozzle in configuration (a). Further, the photoresist material 10 has a material composition that is within the specification range, for example, with a suitable concentration and distribution of photoactive components within the photoresist material, and/or has a viscosity within the desired specification range. This results in an ideal photoresist layer 100 dispensed onto the semiconductor device substrate, such as on a silicon wafer.

Configuration (b) in FIG. 1 illustrates a case in which the photoresist material 10 is sucked back excessively after dispensation of the photoresist material. Configuration (b) can be caused by excessive suction of the photoresist material after a dose of the photoresist material 10 is dispensed onto a top surface of a semiconductor device substrate, such as a silicon wafer. When a dispenser nozzle 60 has excessive suck-back, more photoresist material 10 is drawn back into the dispenser nozzle than an ideal suck-back amount. An excessive suck-back of the photoresist material can result in insufficient coating on the wafer surface (e.g., a void or recess 101 in the photoresist material layer 100), inadequate coverage of the wafer by the photoresist layer, and/or insufficient lithographic process window due to uneven photoresist layer coating thickness.

Configuration (c) in FIG. 1 illustrates a case in which the photoresist material 10 is sucked back insufficiently after dispensation of the photoresist material. Configuration (c) can be caused by insufficient suction of the photoresist material 10 after a dose of the photoresist material is dispensed onto a top surface of a wafer. Insufficient suck-back of the photoresist material 10 can lead to undesired dripping or oozing of excess photoresist material onto the coated wafer, resulting in uneven photoresist layer thickness (e.g., protrusions 102 in the photoresist layer 100) on the wafer. Further, such insufficient suck-back may result in spreading or overflow of the photoresist material beyond the target photoresist dispensation area.

Configuration (d) in FIG. 1 illustrates a case in which a foreign material 11 is present within a portion of the photoresist material 10 within the dispenser nozzle 60. The foreign material 11 may comprise air bubbles and/or dust particles embedded within the photoresist material 10. The presence of the foreign material 11 within a portion of the photoresist material 10 in a dispenser nozzle 11 can have various detrimental consequences for the photoresist layer 100 dispensed onto the wafer and/or on the photoresist dispenser nozzle 60 itself. The foreign material 11 may become embedded in the photoresist layer 100 on the wafer, and may lead to photolithography defects. The foreign material may disrupt the uniformity of the photoresist layer 100 on the wafer, and may adversely affect the precision of a subsequent lithographic exposure process and the integrity of semiconductor device patterns that are subsequently formed.

Configuration (e) in FIG. 1 illustrates a case in which a foreign material 12, such as a dust particle is present at the orifice 61 of the dispenser nozzle 60. The presence of a foreign material 12 at the orifice 61 of the dispenser nozzle 60 can result in disturbance in the application pattern of the photoresist layer 100 onto a wafer, resulting in a non-uniform thickness of the photoresist layer. Further, the foreign material 12 may become embedded in the dispensed photoresist layer 100 on the wafer, and may lead to photolithography defects. The foreign material may disrupt the uniformity of the photoresist layer 100 on the wafer, and may adversely affect the precision of a subsequent lithographic exposure process and the integrity of semiconductor device patterns that are subsequently formed.

Configuration (f) in FIG. 1 illustrates a case in which the photoresist material 10′ in the dispenser nozzle has an abnormal material concentration through deterioration of the photoresist material or through a fluctuation in the composition (e.g., lateral and/or vertical component concentration difference) of the photoresist material. The abnormal material concentration can result in non-uniform photoresist layer 100′ thickness on the wafer after the dispensation process. Such variations in material concentration may lead to irregularities in the photoresist layer 100′, and may adversely affect the precision of a subsequent lithographic exposure process and the integrity of semiconductor device patterns that are subsequently formed.

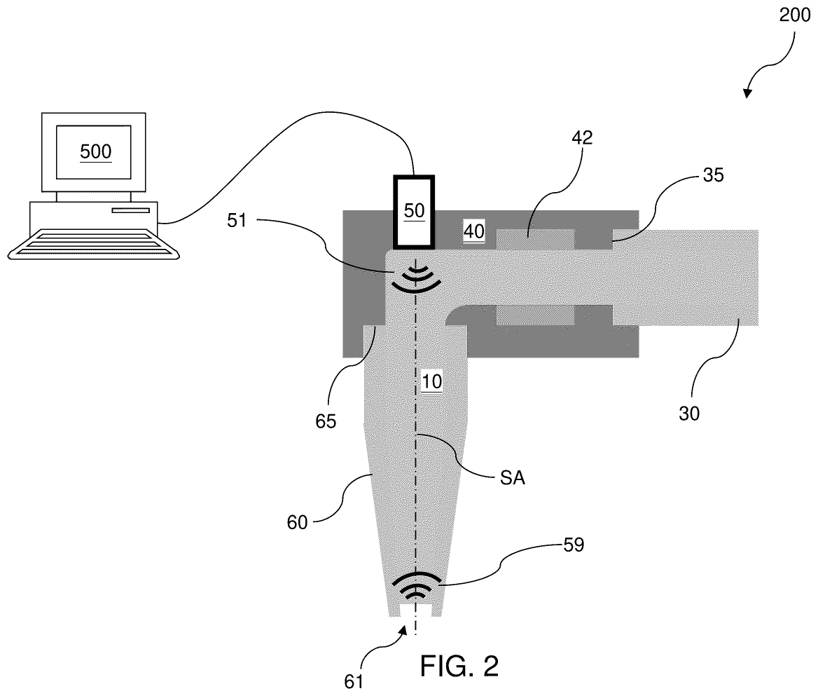

Referring to FIG. 2, a photoresist dispensation system of an embodiment of the present disclosure is illustrated. The photoresist dispensation system comprises a photoresist dispenser 200 including a dispenser head 40, a dispenser nozzle 60 having an orifice 61 configured to dispense a photoresist material 10 and connected to the dispenser head 40, and an ultrasonic unit 50. The ultrasonic unit 50 may be mounted to the dispenser head 40 or may be mounted on another support located adjacent to the dispenser head 40. The ultrasonic unit 50 comprises an ultrasonic wave generator configured to emit transmitted ultrasound waves 51 toward the orifice 61 and further comprising an ultrasonic wave detector configured to detect a reflected ultrasound waves 59 from the bottom surface of the photoresist material 10 in the dispenser nozzle 60. In one embodiment, the ultrasonic unit 50 is mounted directly to or adjacent to the top side of the dispenser head 40 such that the ultrasonic wave generator and detector are positioned above a vertical symmetry axis SA of the dispenser nozzle 60, and such that the transmitted ultrasound waves 51 and the reflected ultrasound waves 59 travel along the vertical symmetry axis SA of the dispenser nozzle 60. The dispenser head 40 may comprise an outlet opening 65 into which an upper end of the nozzle 60 is fitted, and an inlet opening 35 into which a first end portion of a photoresist supply tube 30 is fitted. The opposite second end of the photoresist supply tube 30 may be connected to a photoresist storage reservoir (not shown). In one embodiment, a temperature sensor 42 may be located in the dispenser head 40. The temperature sensor 42 may measure the temperature of the photoresist material (10, 10′) within the dispenser head 40 and/or within the dispenser nozzle 60.

The frequency range of the ultrasound wave that may be utilized for assessing properties of the photoresist material 10 may be in a range from 0.5 MHz to 40 MHz, such as from 1 MHz to 20 MHz, although lower or higher frequencies may also be employed.

During operation of the ultrasound unit 50, the ultrasonic wave generator generates the transmitted ultrasound waves 51 such that the transmitted ultrasound waves 51 travel vertically downstream along the flow path of the photoresist material 10. The ultrasonic wave generator emits the transmitted ultrasound waves 51 downward along the axial direction of the dispenser nozzle 60, e.g., along the vertical symmetry axis SA of the dispenser nozzle 60 in case the dispenser nozzle 60 has an axial rotational symmetry.

The ultrasonic wave detector detects the reflected ultrasound waves 59, which are reflected at each surface in the dispenser nozzle 60 that reflects of the transmitted ultrasound waves 51. The reflected ultrasound waves 59 can be generated at various ultrasound reflective surfaces within or around the dispenser nozzle 60. A surface at which a component of the reflected ultrasound waves 59 is effectively generated includes the physically exposed bottom surface of the photoresist material 10 around the orifice 61 of the dispenser nozzle 60, as well as air bubbles or foreign material 11 embedded in the photoresist material 10 and foreign material 12 located at the orifice 61 of the nozzle 60.

In one embodiment, the ultrasound wave generator is configured to emit the transmitted ultrasound waves 51 along a symmetry axis SA of the nozzle 60. In one embodiment, the nozzle 60 has a continuous rotational symmetry around the symmetry axis SA of the nozzle, and a primary emission direction of the transmitted ultrasound waves 51 coincides with the symmetry axis SA. As used herein, the primary emission direction refers to the direction along which a wave is emitted with the highest amplitude. In one embodiment, the symmetry axis SA of the nozzle 60 is aligned along a vertical direction, and the orifice 61 in the nozzle 60 is located at a bottom portion of the nozzle.

The photoresist dispensation system 200 further comprises a process controller 500, such as a general purpose computer, a special purpose computer or a logic chip) that is configured to determine a property selected from a geometrical feature in or around the photoresist material 10 in the dispenser nozzle 60 or a material property of photoresist material 10 by analyzing a waveform of the reflected ultrasound waves 59.

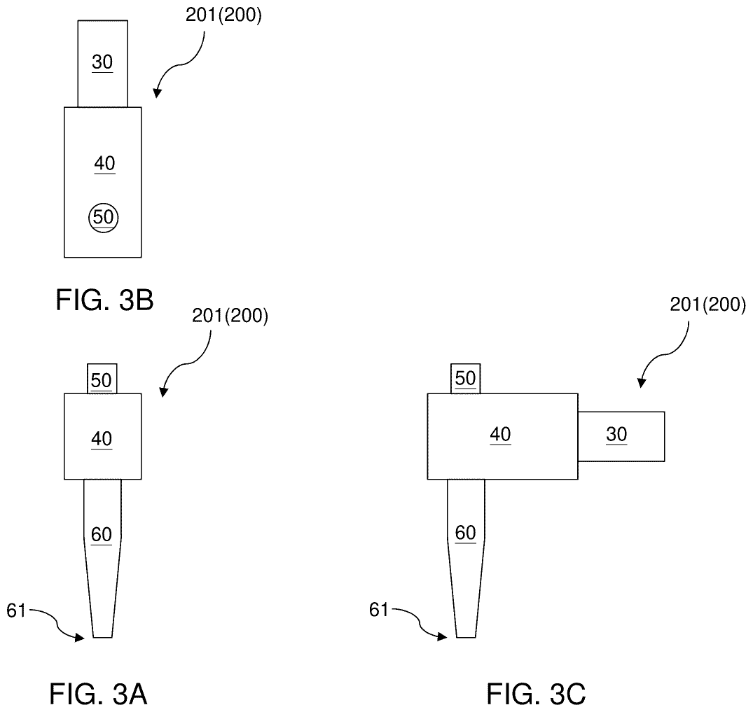

Referring to FIGS. 3A, 3B, and 3C, various views of a single-head photoresist dispenser 201 according to an embodiment of the present disclosure is illustrated. A single-head photoresist dispenser 201 comprises a dispenser head 40, a dispenser nozzle 60 having an orifice 61 configured to dispense a photoresist material 10 and connected to the dispenser head 40, and the ultrasonic unit 50. The dispenser head 40 comprises an inlet opening into which an end portion of the photoresist supply tube 30 is connected.

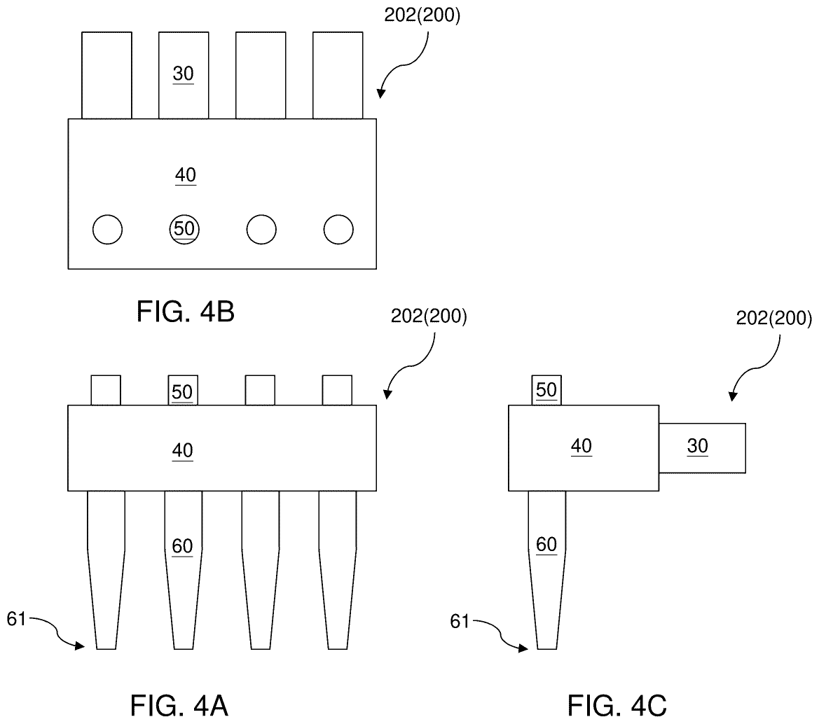

Referring to FIGS. 4A, 4B, and 4C, a multi-head photoresist dispenser 202 according to an embodiment of the present disclosure is illustrated. The multi-head photoresist dispenser 202 can be derived from the single-head photoresist dispenser 201 described with reference to FIGS. 3A, 3B, and 3C by bundling multiple instances of the single-head photoresist dispenser 201 employing a common dispenser head 40. Thus, a multi-head photoresist dispenser 202 comprises a dispenser head 40, a plurality of dispenser nozzles 60 each including a respective orifice 61 configured to dispense a photoresist material 10 and connected to the dispenser head 40, and a plurality of ultrasonic units 50 mounted to or adjacent to the common dispenser head 40. Each ultrasonic unit 50 includes a respective ultrasonic wave generator configured to emit respective transmitted ultrasound waves 51 toward the orifice 61 of the respective nozzle 60 and further comprising an ultrasonic wave detector configured to detect respective reflected ultrasound waves 59 from the respective nozzle 60. The dispenser head 40 comprises an inlet openings into which the end portion of the photoresist supply tube 30 is connected.

Generally, each of the dispenser nozzles 60 of the various configurations of the photoresist dispenser 200 may be ultrasonically examined without any photoresist material 10 therein to provide basic reflection characteristics of the respective dispenser nozzle 60. Further, each of the dispenser nozzles 60 of the various configurations of the photoresist dispenser 200 may be examined with a photoresist material 10 therein to determine the conditions at the orifice 61 to characterize the geometry of the physically exposed surface of the photoresist material 10 near the tip of the nozzle 60 and/or to determine the material property of the photoresist material 10, i.e., to determine any deterioration of the photoresist material 10 in material composition or viscosity.

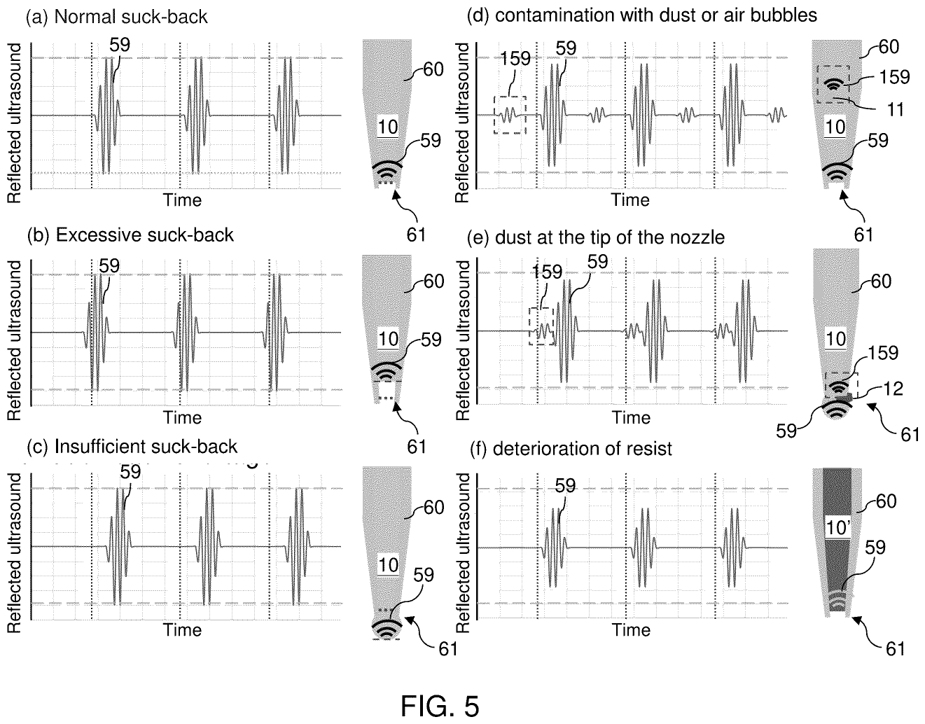

FIG. 5 shows various types of defects that may be present within or around a dispenser nozzle 60 and ultrasound waveforms generated by such defects. The vertical axis represents the reflected ultrasound 59 amplitude (as measured by the ultrasonic wave detector of the ultrasonic unit 50). The horizontal axis represents time. Six configurations, which are labeled with (a), (b), (c), (d), (e), and (f), respectively, are shown in FIG. 5.

Configuration (a) describes a normal operating condition. The transmitted ultrasound waves 51 may be generated as a packet of pulses. Detection of the leading edge of each packet of the reflected ultrasound 59 may occur at the time denoted by the vertical dotted lines. The maximum amplitude of the reflected ultrasound 59 is indicated by the horizontal dashed lines. The waveform of configuration (a) establishes the baseline waveform data to which waveforms of configurations representing an abnormal property of the dispensation system are compared. The abnormal property may comprise a geometrical feature in or around a portion of the photoresist material 10 in the dispenser nozzle 60 and/or a material property of the photoresist material 10′.

Configuration (b) represents the condition of excessive suck-back of the photoresist material 10 into the dispenser nozzle 60. The detection time (i.e., the time between a leading edge of the transmitted ultrasound waves 51 and the leading edge of the reflected ultrasound waves 59) decreases due to the elevation of the physically exposed surface of the photoresist material 10 inside the dispenser nozzle 60 above the orifice 61 of the nozzle.

Configuration (c) represents the condition of insufficient suck-back of the photoresist material 10 into the dispenser nozzle 60. The detection time (i.e., the time between a leading edge of the transmitted ultrasound waves 51 and the leading edge of the reflected ultrasound waves 59) increases due to the lowering of the physically exposed surface of the photoresist material 10 outside the dispenser nozzle 60, i.e., due to presence of a droplet of the photoresist material 10 below the orifice 61 of the nozzle.

Configuration (d) represents the condition of presence of foreign materials (e.g., air bubbles or dust particles) 11 inside the photoresist material 10 within the dispenser nozzle 60. Presence of the foreign materials 11 within the dispenser nozzle 60 can generate an additional low-intensity reflected ultrasound waves 159 before detection of the leading edge of a main component of the reflected ultrasound waves 59 that is generated from the liquid-air interface in proximity to the orifice 61 of the dispenser nozzle 60.

Configuration (f) represents the condition in which a foreign material 12, such as a dust, is present at the orifice 61, and induces insufficient suck-back of the photoresist material 10. In this case, an additional low-intensity reflected ultrasound waves 159 is generated by the foreign material 12, which may arrive at the ultrasonic wave detector of the ultrasonic unit 50 immediately before the arrival of the a main component of the reflected ultrasound waves 59 that is generated from the liquid-air interface in proximity to the orifice 61 of the dispenser nozzle 60 if insufficient suck-back of the photoresist material 10 is also present. If insufficient suck-back of the photoresist material 10 is not present, the additional low-intensity reflected ultrasound waves 159 which is generated by the foreign material 12 may arrive at the ultrasonic wave detector of the ultrasonic unit 50 simultaneously with the arrival of the a main component of the reflected ultrasound 59.

Configuration (f) represents the condition in which material degradation of the photoresist material 10′ occurs and/or properties of the photoresist material 10′ change. In this case, a change in amplitude of the reflected ultrasound waves 59 may be detected.

As discussed above, the photoresist dispensation system comprises a process controller 500 that is configured to determine a property selected from a geometrical feature in or around the photoresist material 10 in the dispenser nozzle 60 or a material property of the photoresist material 10′ by analyzing a waveform of the reflected ultrasound waves 59.

In one embodiment, the property comprises a distance of a physically exposed surface of the photoresist material 10 from the ultrasonic unit 50. Generally, the physically exposed surface of the photoresist material 10 is located at or near the orifice 61 of the nozzle 60. The process controller 500 may be loaded with a waveform analysis program that can analyze the waveform of the reflected ultrasound waves 59 (as measured by the ultrasonic wave detector within the ultrasonic unit 50). In this case, the process controller 500 can determine whether the physically exposed surface of the photoresist material is located outside of a volume of the dispenser nozzle 60 (as illustrated in configuration (c) in FIG. 5), inside the volume of the dispenser nozzle 60 (as illustrated in configuration (b) in FIG. 5), or at the orifice 61 of the nozzle 60 (as illustrated in configuration (a) in FIG. 5). In one embodiment, the distance may be determined by measuring a signal delay time between emission of the transmitted ultrasound waves 51 and a component of the reflected ultrasound waves 59 that is generated by the physically exposed surface of the photoresist material 10.

In one embodiment, the property that is determined by the process controller 500 may comprise presence of a foreign material 11 within a volume of the photoresist material 10 in the dispenser nozzle 60 (as illustrated in configuration (d) in FIG. 5). In one embodiment, the presence of the foreign material 11 is measured by presence of a component of the reflected ultrasound waves 159 that precedes a component of the reflected ultrasound waves 59 that is caused by a physically exposed surface of the photoresist material 10 around the orifice 61 of the nozzle 60. This is due to the proximity of the foreign materials 11 in the photoresist material 10 of the dispenser nozzle 60 relative to the physically exposed surface of the photoresist material 10 that is located near the orifice 61 of the nozzle 60.

In one embodiment, the property that is determined by the process controller 500 may comprise presence of a foreign material 12 on the orifice 61 of the nozzle (as illustrated in configuration (e) in FIG. 5). In one embodiment, the presence of the foreign material 12 is measured by presence of an anomaly in a wave pattern in a component of the reflected ultrasound waves 59 that is caused by a physically exposed surface of the photoresist material 10 around the orifice 61 of the nozzle.

In one embodiment, the property that is determined by the process controller 500 may comprise a parameter in a material composition of the photoresist material 10′ in the dispenser nozzle 60 (as illustrated in configuration (e) in FIG. 5). In one embodiment, the parameter may comprise a concentration of photoactive components or the photoresist viscosity within the photoresist material 10′ in the dispenser nozzle 60. In one embodiment, a temperature sensor 42 may be located in the dispenser head 40. The temperature sensor 42 may measure the temperature of the photoresist material 10′ within the dispenser head 40 and/or within the dispenser nozzle 60. The process controller 500 may determine the composition and/or viscosity of the photoresist material 10′ based on the combination of the reflected ultrasound waves 59 and the photoresist material 10′ temperature.

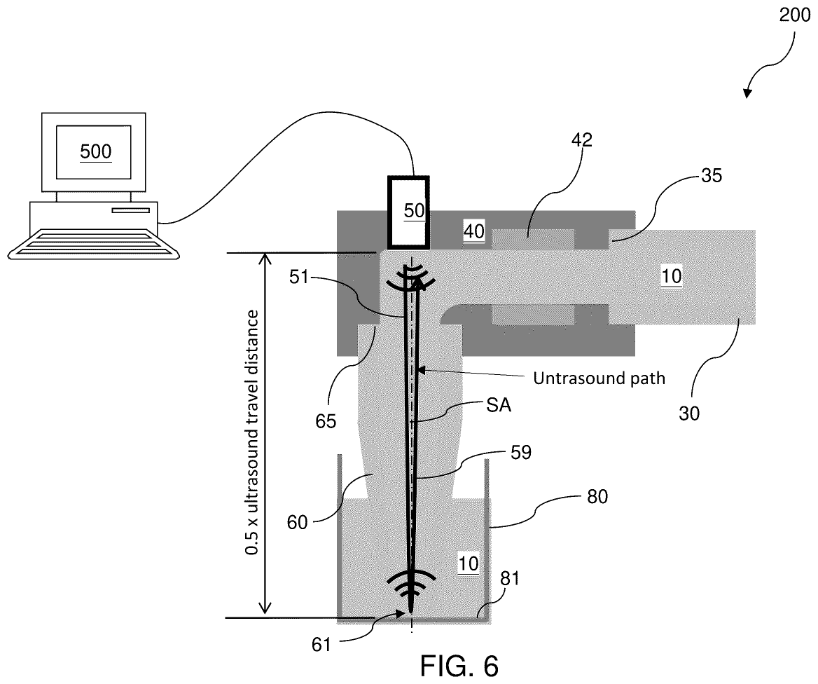

Referring to FIG. 6, an alternative measurement configuration for measuring a material property of a photoresist material 10 employing the photoresist dispensation system 200 is illustrated. In this case, the process controller 500 can measure and determine a parameter in the material composition of the photoresist material 10 in the dispenser nozzle 60. In one embodiment, the temperature sensor 42 can be located on the dispenser head 40, and the parameter comprises a concentration of photoactive components within the photoresist material 10 in the dispenser nozzle 60. A liquid container 80 may be employed to provide an additional portion of the photoresist material 10 around the orifice 61 of the dispenser nozzle 60. Thus, the photoresist material 10 within the liquid container 80 can laterally surround the dispenser nozzle 60.

In one embodiment, the dispenser nozzle 60 can establish physical contact with a reflective surface 81 of the liquid container 80. For example, the reflective surface 81 may be the bottom surface of the liquid container 80. The reflective surface 81 functions as a reliable location for generating the reflected ultrasound waves 59 within the photoresist material 10 in the dispenser nozzle 60. The temperature of the photoresist material 10 in the dispenser nozzle 60 can be monitored by the temperature sensor 42 (such as a thermometer or thermocouple). The shortest path for the leading edge of the ultrasound waves includes a downward path from the ultrasonic unit 50 to the reflective surface 81 along the symmetry axis SA of the dispenser nozzle 60, and an upward path from the reflective surface 81 to the ultrasonic unit 50 along the symmetry axis SA of the dispenser nozzle 60. Thus, the vertical distance between the ultrasonic unit 50 and the reflective surface 81 is equal to 0.5 times the ultrasound wave travel distance for the leading edge of the reflected ultrasound 59 that is detected by the ultrasonic wave detector within the ultrasonic unit 50.

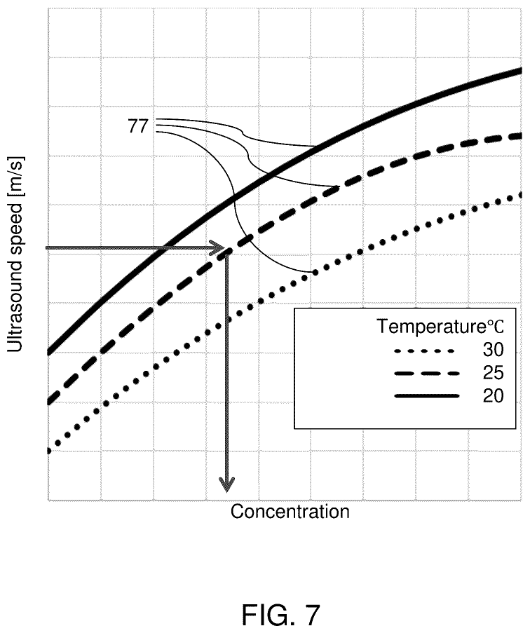

Referring to FIG. 7, a graph illustrates the dependence of the speed of the ultrasound waves within a photoresist material 10 as a function of temperature and as a function of a concentration of photoactive components. The photoresist material 10 includes a mixture of photoactive components and a solvent. In order for a photoresist material 10 to function properly during a lithographic exposure process and during a subsequent lithographic development process, the concentration of the photoactive components within the photoresist material 10 is desired to be within a specification range.

Generally, calibration curves 77 for the velocity of the ultrasound may be generated as a function of the concentration of the photoactive components within the photoresist material 10 for a set of selected temperatures. The speed of the ultrasound waves can be calculated from the data generated from the measurement described with reference to FIG. 6. Specifically, the speed of the ultrasound waves is twice the vertical distance between the ultrasonic unit 50 and the reflective surface 81 in the text set-up illustrated in FIG. 6 divided by the time delay between emission of a transmitted ultrasound waves 51 from the ultrasonic unit 50 and detection of the reflected ultrasound waves 59 by the ultrasonic unit 50.

Once the temperature of the photoresist material 10 and the measured speed of the ultrasound waves in the photoresist material 10 is known, the concentration of the photoactive component within a photoresist material 10 may be determined employing the calibration curves 77 in the graph illustrated in FIG. 7.

Thus, the photoresist dispensation system 200 can determine a property related to the dispenser nozzle 60 or the photoresist material 10. The property may be a geometrical feature in or around a portion of the photoresist material 10 in the dispenser nozzle 60, and/or a material property of the photoresist material 10. The property may be determined by analyzing a waveform of the reflected ultrasound waves 59 and by optionally measuring a temperature of the photoresist material 10.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A method, comprising:
providing a photoresist material into a dispenser nozzle having an orifice;
emitting transmitted ultrasound waves through the photoresist material in the dispenser nozzle toward the orifice;
detecting reflected ultrasound waves; and
determining a property of the photoresist material or the nozzle by analyzing a waveform of the detected reflected ultrasound waves.

2. The method of claim 1, wherein the property comprises a distance of a physically exposed surface of the photoresist material from the ultrasonic unit.

3. The method of claim 2, further comprising determining whether the physically exposed surface is located outside of a volume of the dispenser nozzle, inside the volume of the dispenser nozzle, or at the orifice of the dispenser nozzle.

4. The method of claim 2, wherein the distance is determined by measuring a signal delay time between emission of the transmitted ultrasound waves and a component of the reflected ultrasound waves that are reflected from the physically exposed surface of the photoresist material.

5. The method of claim 1, wherein the property comprises presence of a foreign material embedded within the photoresist material in the dispenser nozzle.

6. The method of claim 5, wherein the presence of the foreign material is determined by presence of a component of the reflected ultrasound waves that precedes a component of the reflected ultrasound waves that are reflected from a physically exposed surface of the photoresist material around the orifice of the nozzle.

7. The method of claim 1, wherein the property comprises presence of a foreign material on the orifice of the nozzle.

8. The method of claim 7, wherein the presence of the foreign material is determined by presence of an anomaly in a wave pattern in a component of the reflected ultrasound waves that that are reflected from a physically exposed surface of the photoresist material around the orifice of the nozzle.

9. The method of claim 1, wherein the property comprises a parameter of a material composition of the photoresist material in the dispenser nozzle.

10. The method of claim 9, wherein the parameter comprises a concentration of photoactive components within the photoresist material in the dispenser nozzle.

11. The method of claim 1, wherein:
the dispenser nozzle comprises a portion of a photoresist dispenser; and
the photoresist dispenser further comprises a dispenser head and an ultrasonic unit mounted on or adjacent to the dispenser head, and comprising an ultrasonic wave generator and an ultrasonic wave detector;
the transmitted ultrasound waves are emitted by the ultrasonic wave generator; and
the reflected ultrasound waves are detected by the ultrasound wave detector.

12. The method of claim 11, wherein:
the ultrasound wave generator emits the transmitted ultrasound waves along a symmetry axis of the nozzle;
the nozzle has a continuous rotational symmetry around the symmetry axis of the nozzle;
a primary emission direction of the transmitted ultrasound waves coincides with the symmetry axis;
the symmetry axis of the nozzle is aligned along a vertical direction; and
the orifice in the nozzle is located at a bottom portion of the nozzle.

13. The method of claim 11, wherein the dispenser head comprises:
an outlet opening into which an upper end of the nozzle is fitted;
an inlet opening into which an end portion of a photoresist supply tube is fitted; and
a temperature sensor.

14. The method of claim 1, further comprising dispensing the photoresist material from the dispenser nozzle through the orifice onto a semiconductor device substrate.

15. A photoresist dispenser, comprising:
a dispenser head;
a dispenser nozzle having an orifice configured to dispense a photoresist material, wherein the dispenser nozzle is connected to the dispenser head; and
an ultrasonic unit mounted on or adjacent to the dispenser head and comprising:
an ultrasonic wave generator configured to emit a transmitted ultrasound waves through the nozzle toward the orifice; and
an ultrasonic wave detector configured to detect reflected ultrasound waves.

16. The photoresist dispenser of claim 15, wherein the ultrasound wave generator is configured to emit the transmitted ultrasound waves along a symmetry axis of the nozzle.

17. The photoresist dispenser of claim 16, wherein:
the nozzle has a continuous rotational symmetry around the symmetry axis of the nozzle; and
a primary emission direction of the transmitted ultrasound waves coincides with the symmetry axis.

18. The photoresist dispenser of claim 17, wherein:
the symmetry axis of the nozzle is aligned along a vertical direction; and
the orifice in the nozzle is located at a bottom portion of the nozzle.

19. The photoresist dispensation system of claim 15, wherein the dispenser head comprises:
an outlet opening into which an upper end of the nozzle is fitted; and
an inlet opening into which an end portion of a photoresist supply tube is fitted.

20. A photoresist dispensation system, comprising:
the photoresist dispenser of claim 15; and
a process controller configured to determine a property selected from a geometrical feature in or around the photoresist material located in the dispenser nozzle or a material property of the photoresist material by analyzing a waveform of the reflected ultrasound waves.
